(19) United States
(12) Patent Application Publication
(10) Pub. No.: US 2006/0220013 A1
(43) Pub. Date: Oct. 5, 2006

(54) Techniques for facilitating identification updates in an integrated circuit

(76) Inventors: Steven C. Bachman, Germansville, PA (US); Lynn G. Edwards JR., Kutztown, PA (US)

Correspondence Address: Ryan, Mason & Lewis, LLP, 90 Forest Avenue, Locust Valley, NY, 11560, US

(21) Appl. No.: 11/092,009

(22) Filed: Mar. 29, 2005

(51) Int. Cl. H01L 23/58; H01L 29/10

(52) U.S. Cl. 257/48

(57) ABSTRACT

An integrated circuit comprises an identification portion having an output representative of one or more bits of digital information identifying the integrated circuit. This identification information may, for example, allow the manufacturer to determine which photolithographic masks were used to manufacture the integrated circuit. The identification portion is formed at least partially by a plurality of metal levels. Modifications to the integrated circuit's identification information are facilitated by designing the identification portion such that its output can be changed by modifying any one metal level among the plurality of metal levels that form it.

### FIELD OF THE INVENTION

This invention relates to integrated circuits, and, more specifically, to integrated circuits containing electronically readable identification information.

### BACKGROUND OF THE INVENTION

Modern integrated circuits commonly include one or more means by which the integrated circuit can be identified. This identification information may, for example, allow the manufacturer to determine which photolithographic masks (“masks”) were used to manufacture the integrated circuit. Masks are frequently changed in order to reduce defects, increase performance or change a circuit design. Embedded identification information allows the manufacturer to readily track such changes.

Many manufacturers indicate mask revisions simply by changing a designator on the masks being revised. The designator is subsequently patterned into the integrated circuit and is available to the manufacturer by optical inspection. While such a method may provide identification information while the integrated circuit is being manufactured, such physical identifiers are no longer available after an integrated circuit is encapsulated in an integrated circuit package. As a result, many modern manufacturers choose to encode their integrated circuits with electronically readable identification information. Such identification information may include, for example, 32 bits of digital data.

Electronically readable identification information is frequently encoded into an integrated circuit using logic cells formed by one or more of the top levels of metallization. Accordingly, when the masks used to manufacture the integrated circuits are changed, all of these one or more top metal levels must also be altered so that the logic cells properly identify the changes. If, as is frequently the case, the revisions to the integrated circuit do not happen to involve those top metal mask levels that conventionally form the identification portion of the integrated circuit, then new masks must be created specifically to change the identification information. This creates significant added cost. Masks may cost $15,000 to $35,000 each.

It would, therefore, be advantageous to a have an identification portion of an integrated circuit that could be easily and quickly updated to reflect new identification information by way of changes to any one of many masks, not just changes to the top one or more metal levels that conventionally form the identification portion of the integrated circuit.

### SUMMARY OF THE INVENTION

The present invention addresses the above-identified need with an integrated circuit comprising an identification portion that is formed by a plurality of metal levels. Modifications to the integrated circuit's identification information are facilitated by designing the identification portion such that its output can be changed by modifying any one metal level among the plurality of metal levels that form it.

In accordance with an aspect of this invention, an integrated circuit comprises an identification portion having an output representative of one or more bits of digital information identifying the integrated circuit. In addition, the integrated circuit has one or more additional portions including active circuitry of the integrated circuit. The identification portion and the one or more additional portions are formed at least partially from a plurality of metal levels. Moreover, the output of the identification portion can be changed by modifying any one level in the plurality of metal levels.

In an illustrative embodiment, an identification portion of an integrated circuit has an output representing one bit of digital information identifying the integrated circuit. The identification portion is formed of seven metal levels and includes a source of high and low voltage levels. Several metal link features on each of the metal levels connect to lower and higher metal levels through metal vias. The metal links and vias are configured such that the output of the identification can be easily flipped from low to high or high to low by the addition and removal of a metal link from any one of the seven metal levels that form the identification portion. The output can subsequently be flipped a number of more times by adding and removing metal links on any one of the other metal levels or even on a metal level that may have been modified earlier. This illustrative embodiment of a one bit identification portion can, therefore, have its output flipped several times by modifying one metal level each time without any pre-determined order.

Advantageously, when any one of the metal levels that form the identification portion need to be modified to implement various revisions to the remainder of the integrated circuit, the output of the identification portion can also be changed on the same mask so that the integrated circuit's identification information reflects the revisions. For example, if a single metal layer that forms a part of the identification portion needs to be changed to correct a design error somewhere in the active portion of the integrated circuit, the same metal layer can be concurrently modified to change the identification portion such that its output reflects this design change. The cost of additional masks exclusively for the purpose of updating identification information is thereby avoided.

### BRIEF DESCRIPTION OF THE DRAWINGS

FIGS. 1A-1E show electrical schematics of illustrative embodiments of an identification portion of an integrated circuit in accordance with this invention.

FIG. 2A shows a layout view of a portion of the FIG. 1A identification portion embodiment.

FIG. 2B shows a cross-sectional view of the FIG. 2A layout.

FIG. 3 shows an illustrative embodiment of a semiconductor wafer in accordance with this invention.

FIG. 4 shows an illustrative embodiment of an integrated circuit mounted in a integrated circuit package in accordance with this invention.

### DETAILED DESCRIPTION OF THE INVENTION

The present invention will be illustrated below in conjunction with illustrative embodiments of an integrated circuit. It should be understood, however, that the invention is not limited to the particular circuitry arrangements of the illustrative embodiments. An integrated circuit could, for example, contain a different number and arrangement of metal levels from that described by the illustrative embodiments and still fall within the scope of the invention. Other possible modifications to the illustrative embodiments within the scope of this invention will be apparent to those skilled in the art.

In accordance with one aspect of the invention, an integrated circuit comprises at least two portions. An identification portion has an output that represents one or more bits of digital information identifying the integrated circuit. Furthermore, one or more additional portions of the integrated circuit include active circuitry. The active circuitry may contain digital or analog circuit components and may perform logic and/or memory functions. Because the identification portion need only comprise a few bits of digital information, it will typically occupy only a small percentage of the total area of the integrated circuit.

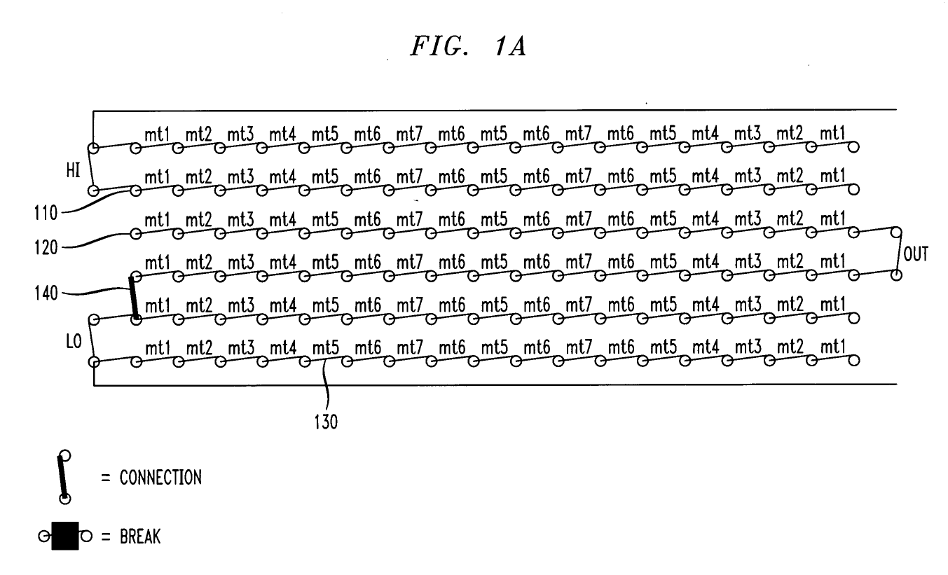

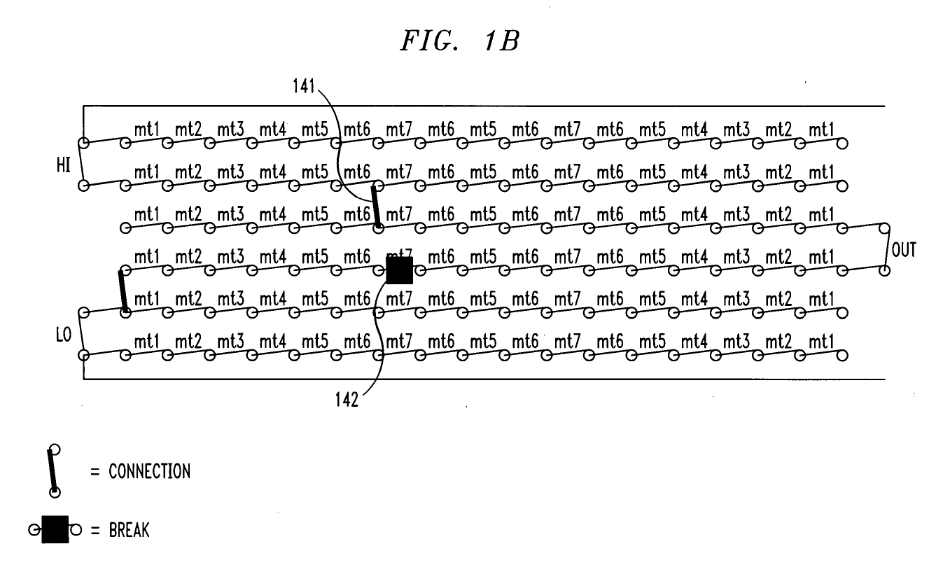

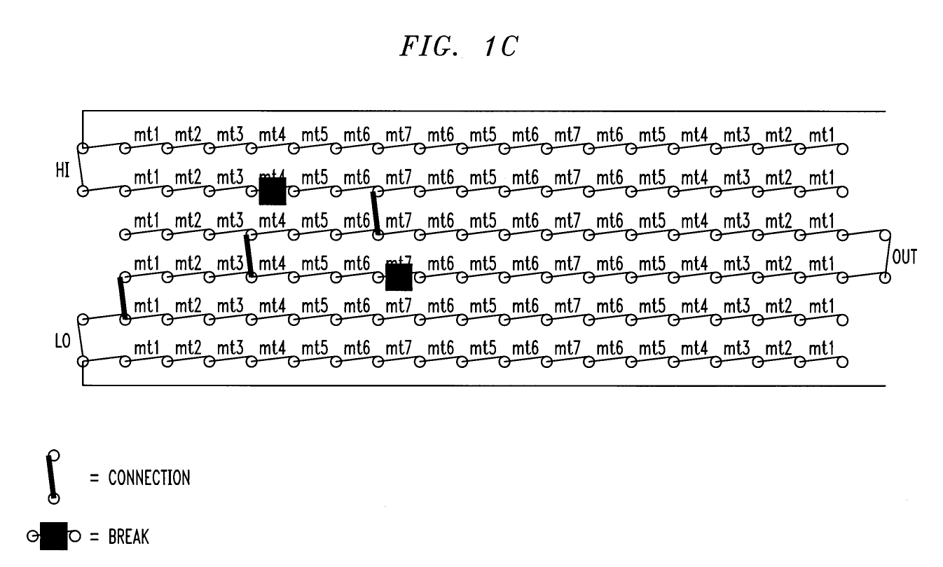

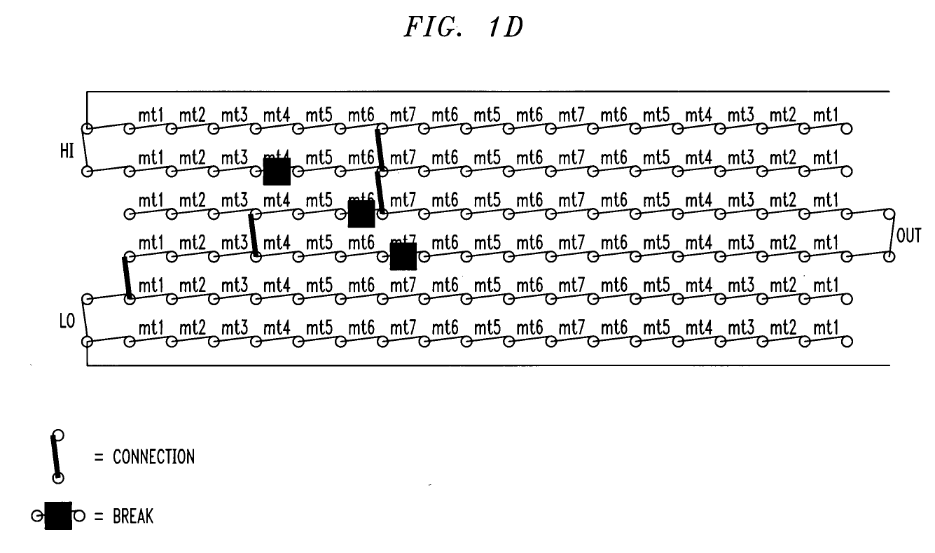

FIG. 1A shows an electrical schematic of an illustrative embodiment of identification portion of an integrated circuit in accordance with this invention. This identification portion consists of seven metal levels, labeled on the figures as “mt1” through “mt7.” In addition to the metal levels, there are a plurality of vias that connect the metal features on one metal level with metal features on levels above or below that feature. The vias are collectively represented by vias 110 and 120. The majority of the metal features on any given metal level are metal links, represented collectively by metal link 130, that connect one via to another.

The output of the FIG. 1A embodiment is one bit of digital information. Correspondingly high and low voltage sources are provided, labeled “hi” and “lo,” respectively. In the illustrative embodiment shown in FIG. 1A, the output is currently configured to be low. This is achieved by adding metal link 140 such that it bridges two vias on the metal one level. The output is thereby connected through the many metal levels to the low voltage source. It should be noted however, that the initial configuration of the FIG. 1A is largely arbitrary and meant to be illustrative. The output of the FIG. 1A embodiment could just as easily be set to high by placing link 140 somewhere else, for example, so that it bridges vias 110 and 120.

FIGS. 1B-1E show how the output of the FIG. 1A identification portion embodiment can be changed several times by adding a link and removing a link on one metal level and then repeating the process on a different metal level. It should be noted that there is no predefined or preferred order to the way the different mask levels are modified in progressing from FIG. 1B to FIG. 1E. When utilized in an integrated circuit manufacturing process, the order in which the metal levels are modified to change the output of the identification portion will reflect the order in which metal levels are modified in order to address various issues in the active regions of the integrated circuit. For illustrative purposes, the order in which the metal levels are modified in progressing from FIGS. 1B through 1E is chosen to be somewhat random. FIG. 1B illustrates the ability to change the output of the FIG. 1A embodiment by making a modification to metal seven level. In order to change the output of the FIG. 1A embodiment from low to high, metal link 141 is added while metal link 142 is broken or entirely removed.

FIG. 1C shows how the output can again be flipped to low by adding and removing metal links on the metal four level. Similarly, FIGS. 1D and 1E illustrate the adding and removing of metal links on metal six level and metal one level, respectively. The circuit showing in FIG. 1D has a high output. The circuit shown in FIG. 1E has a low output.

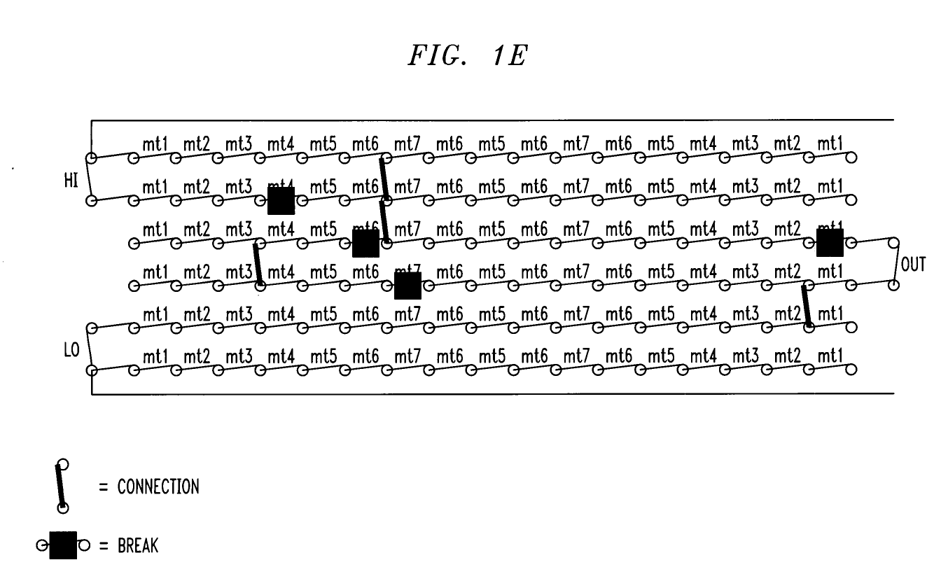

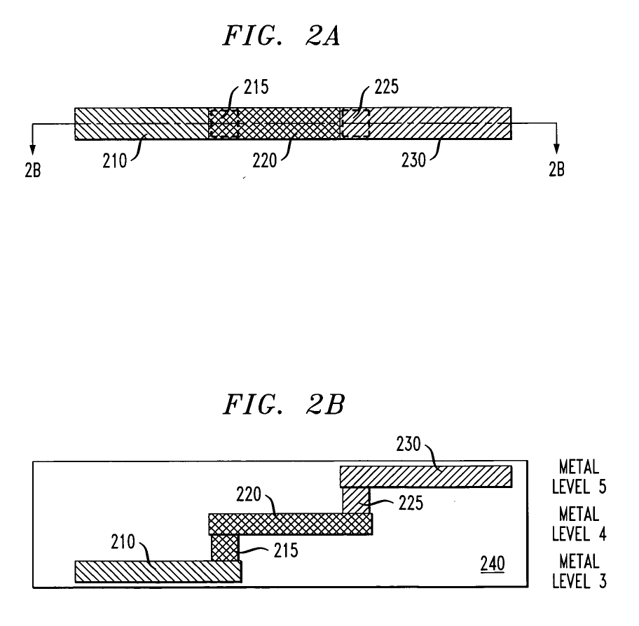

FIG. 2A shows a layout view of a small portion of the FIG. 1A identification portion embodiment. For illustrative purposes and because of the repetitive nature of the connections, FIG. 2A shows only how metal links at metal levels three, four and five might be implemented physically on an integrated circuit. FIG. 2B shows a corresponding cross-sectional view. Metal link 210 is found on metal three level. It connects through via 215 to metal link 220 which is found on metal four level. Metal link 220 is connected, in turn, through via 225 to metal link 230 on metal five level. Interlevel dielectric material 240 surrounds the metal features.

Alternatively, each metal link on a given metal level could use more than one via to connect to a metal link on a different metal level. The use of more than one via may provide a lower resistance electrical connection between metal levels. Moreover, more than one via will create useful redundancy in case of defects. These possible variations and their relative advantages will be familiar to one skilled in the art.

The number of times the output of any given one bit identification portion such as that shown in FIGS. 1A-1E can be changed is determined by the sequence in which the metal levels are modified. Capacity for changing the output will be decreased when metal levels are modified one at a time since this will not allow the removal of the added links that act to effectively cut off sections of the circuit. Of course, if all the metal levels are changed at once, such as might occur with a major revision to the design of the integrated circuit, the identification portion can be reset back to its original configuration.

As described earlier, a integrated circuit manufacturer will frequently make changes to the masks used to manufacture an integrated circuit while a given type of integrated circuit is being developed and manufactured. As a result, the ability to identify a given integrated circuit is frequently important to the manufacturer of integrated circuits in order to determine the effects of these changes. For example, a manufacturer may decide to change the dimensions of various features at a given mask level in an attempt to enhance circuit performance. Those integrated circuits receiving the modified mask level would also have their identification portion modified to reflect this change. Later, when the integrated circuits are being tested for performance, the manufacturer can easily determine which integrated circuits did and did not receive the modified mask level earlier in the manufacturing process. The result of the modification can thereby be readily determined.

The identification portion may also communicate various other types of information about the integrated circuit and come within the scope of this invention. In addition to identifying which masks were used to manufacture a given integrated circuit, the identification portion may, for example, contain information indicative of where the integrated circuit was manufactured, when the integrated circuit was manufactured, what processing steps were used to manufacture the integrated circuit, what manufacturing tools were utilized in manufacturing the integrated circuit, and/or what integrated circuit designs are incorporated into the integrated circuit.

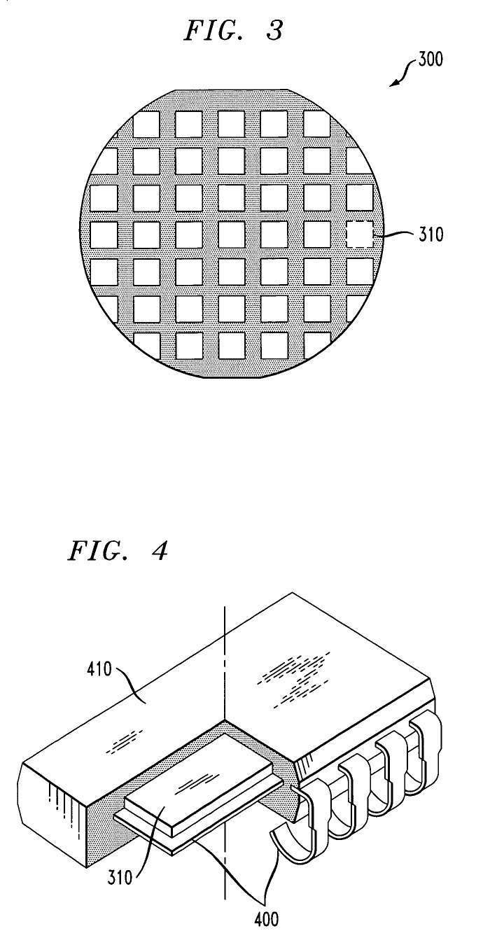

FIG. 3 shows a semiconductor wafer 300 with electrical circuits formed thereon so as to describe a plurality of discrete integrated circuits, represented collectively by integrated circuit 310. A typical wafer can incorporate between 500 and 1,200 integrated circuits depending on the technology. Various methods for forming such integrated circuits are commonly practiced and will be known to those skilled in the art. Processing steps that may be used in such methods include, but are not limited to: deposition, growth, etching, photolithography, polishing, cleaning, stripping, annealing and ion implanting. These processing steps are described in detail in a number of publications, including, for example, S. Wolf and R. N. Tauber, Silicon Processing for the VLSI Era, Volume 1 (1986), which is incorporated herein by reference.

In accordance with an aspect of the invention, the identification portion is formed at least partially by a plurality of metal levels. Metal features are frequently used in integrated circuits to form electrical interconnects and can also be used as active components in some devices such as metal-insulator-metal capacitors. Metal interconnects are most commonly formed of aluminum, copper or tungsten. Interlevel dielectrics are frequently formed of silicon dioxide.

To achieve many of the benefits of the present invention, it is preferable that the metal levels that form the identification portion of an integrated circuit be formed at the same time that other metal levels are formed in the remainder of the integrated circuit. By doing this, extra processing steps exclusively for forming the identification portion are avoided. Metal features are typically formed on integrated circuits using one of two different processing sequences. Both of these process sequences will be familiar to those skilled in the art. The first process sequence is frequently referred to as a “dual damascene process.” In this sequence, a trench is first patterned into an interlevel dielectric layer using a combination of photolithography and reactive ion etching. The trench is formed in the shape of the metal features that are desired, including the vias. Next, metal is deposited on the interlevel dielectric. The metal deposits both inside the metal trenches and on top of the upper surface of the dielectric. Subsequently, chemical mechanical polishing is used to remove the metal from the upper surface of the interlevel dielectric. What remains are discrete metal features, like those shown in FIGS. 2A and 2B, formed inside the etched trenches.

The second processing sequence involves first depositing a blanket layer of metal on top of an interlevel dielectric. A photolithographic mask and reactive ion etching are then used to pattern the metal layer into the discrete metal features that are desired. An interlevel dielectric may subsequently be deposited in between the etched metal features.

After processing the semiconductor wafer, a wafer dicing process is used to break up the semiconductor wafer into discrete integrated circuits. The process of wafer dicing is not altered by implementation of the present invention and, therefore, will also be familiar to one skilled in the art. Typically, the wafer dicing process involves a rotating abrasive disk which acts as a blade to divide the wafer. The blade is typically made of abrasive diamonds, which are embedded in an electroplated nickel matrix binder. During the dicing of the integrated circuits, the blade simultaneously crushes the substrate material and removes the created debris.

After wafer dicing is completed, the integrated circuit is typically packaged. There are a wide variety of packaging technologies that are compatible with the present invention such as, but not limited to, plastic leadframe-based technologies and hermetic packaging technologies. These technologies and others are described in, e.g., S. M. Sze, VLSI Technology (2d ed. 1988), which is incorporated herein by reference. The integrated circuit package has metal leads that are connected to the integrated circuit. These connections allow the outputs of the integrated circuit, including the output from the identification portion, to be electronically determined once the integrated circuit is encapsulated.

FIG. 4 shows an illustrative embodiment of the the integrated circuit 310 incorporated into a plastic leadframe-based package. Integrated circuit 310 is mounted on a metal leadframe 400 using a thermally conductive, reflowable material such as gold alloy, soft lead-tin solder, or epoxy. A molding compound 410 acts to encapsulate and support the integrated circuit 310 and the leadframe 400. Again, the particular package assembly shown is not a requirement of this invention, and this and other packages suitable for use with the present invention will be familiar to those skilled in the art.

Finally, it should once more be emphasized that the above-described embodiments of the invention are intended to be illustrative only. Other embodiments can use different types and arrangements of elements for implementing the described functionality. These numerous other alternative embodiments within the scope of the following claims will be apparent to one skilled in the art.

What is claimed is:

1. An integrated circuit comprising:
an identification portion having an output representative of one or more bits of digital information identifying the integrated circuit; and
one or more additional portions including active circuitry of the integrated circuit;
wherein the identification portion and the one or more additional portions are formed at least partially from a plurality of metal levels, and the output of the identification portion can be changed by modifying any one metal level in the plurality of metal levels.

2. The integrated circuit of claim 1 wherein the identification portion is formed at least partially by three or more metal levels.

3. The integrated circuit of claim 1 wherein changing the output of the identification portion comprises removing a metal feature on any one metal level in the plurality of metal levels.

4. The integrated circuit of claim 1 wherein changing the output of the identification portion comprises forming a metal feature on any one metal level in the plurality of metal levels.

5. The integrated circuit of claim 1 wherein the plurality of metal levels that at least partially form the identification portion comprises:
a metal link formed on a metal level;
a lower metal level below the metal level on which the metal link is formed;
a higher metal level above the metal level on which the metal link is formed;
a first via connecting the metal link to the lower metal level; and
a second via connecting the metal link to the higher metal level.

6. The integrated circuit of claim 1 wherein the identification portion at least identifies a manufacturing location where the integrated circuit was manufactured.

7. The integrated circuit of claim 1 wherein the identification portion at least identifies a photolithographic mask that was used to manufacture the integrated circuit.

8. The integrated circuit of claim 1 wherein the identification portion at least identifies when the integrated circuit was manufactured.

9. The integrated circuit of claim 1 wherein the identification portion at least identifies a circuit design incorporated into the integrated circuit.

10. The integrated circuit of claim 1 wherein the identification portion at least identifies a process used to manufacture the integrated circuit.

11. The integrated circuit of claim 1 wherein the integrated circuit is mounted in an integrated circuit package.

12. A semiconductor wafer comprising a plurality of integrated circuits, at least one of the plurality of integrated circuits comprising:
an identification portion having an output representative of one or more bits of digital information identifying the integrated circuit; and
one or more additional portions including active circuitry of the integrated circuit;
wherein the identification portion and the one or more additional portions are formed at least partially from a plurality of metal levels, and the output of the identification portion can be changed by modifying any one metal level in the plurality of metal levels.

13. A method for forming an integrated circuit comprising the steps of:
forming an identification portion having an output representative of one or more bits of digital information identifying the integrated circuit; and
forming one or more additional portions including active circuitry of the integrated circuit;
wherein the identification portion and the one or more additional portions are formed at least partially from a plurality of metal levels, and the output of the identification portion can be changed by modifying any one metal level in the plurality of metal levels.

14. The method of forming an integrated circuit of claim 13 wherein at least one of the plurality of metal levels is formed at least partially by the steps of depositing metal and etching metal.

15. The method of forming an integrated circuit of claim 13 wherein at least one of the plurality of metal levels is formed at least partially by the steps of etching a dielectric material, depositing metal and polishing metal.

16. The method of forming an integrated circuit of claim 13 further comprising dicing a semiconductor wafer.

17. The method of forming an integrated circuit of claim 13 further comprising the step of mounting the integrated circuit in an integrated circuit package.

18. A mask set for forming an integrated circuit comprising a plurality of masks capable of being used to form an identification portion having an output representative of one or more bits of digital information identifying the integrated circuit, and capable of being used to form one or more additional portions including active circuitry of the integrated circuit, wherein the identification portion and the one or more additional portions are formed at least partially from a plurality of metal levels, and the output of the identification portion can be changed by modifying any one metal level in the plurality of metal levels.
